(19) United States
(12) Patent Application Publication
(10) Pub. No.: US 2024/0332299 A1
(43) Pub. Date: Oct. 3, 2024

(54) INTEGRATED CIRCUIT DEVICE WITH HETEROGENOUS TRANSISTORS

(71) Applicant: Intel Corporation, Santa Clara, CA (US)

(72) Inventors: Abhishek Anil Sharma, Portland, OR (US); Van Le, Beaverton, OR (US); Sudipto Naskar, Portland, OR (US); Sukru Yemenicioglu, Portland, OR (US)

(73) Assignee: Intel Corporation, Santa Clara, CA (US)

(21) Appl. No.: 18/192,601

(22) Filed: Mar. 29, 2023

(51) Int. Cl. H01L 27/092

(52) U.S. Cl. CPC H01L 27/0922

(57) ABSTRACT

An integrated circuit device comprising a plurality of first field effect transistors (FETs) formed on a substrate, wherein a first FET comprises a first channel material comprising a portion of the substrate; and a plurality of second FETs formed on the substrate, wherein a second FET comprises a second channel material that is different from the first channel material, wherein the second channel material comprises a thin film transistor (TFT) channel material.

### BACKGROUND

In various process nodes, it is difficult to manufacture high voltage transistors along with standard (e.g., lower voltage) transistors due the significant pitch difference between the high voltage transistors (which generally have thicker gate dielectric layers) and standard transistors. High voltage transistors may be suitable for input/output (I/O) operations and constraints on manufacturing of such transistors may limit the ability to add I/O devices and charge pumps to an integrated circuit device while maintaining efficient power delivery.

### BRIEF DESCRIPTION OF THE DRAWINGS

FIGS. 1A-1D illustrate portions of example integrated circuit devices comprising heterogeneous transistors, in accordance with any of the embodiments disclosed herein.

FIGS. 2A-2B illustrate example top-gated transistors, in accordance with any of the embodiments disclosed herein.

FIGS. 3A-B illustrate example recessed gate transistors, in accordance with any of the embodiments disclosed herein.

FIG. 4 illustrates an example recessed spherical shaped gate transistor, in accordance with any of the embodiments disclosed herein.

FIGS. 5A-5B illustrate a cross sections of example nanowire based transistor architectures, in accordance with any of the embodiments disclosed herein.

FIG. 6 illustrates an example backgate transistor, in accordance with any of the embodiments disclosed herein.

FIG. 7 illustrates a method for forming heterogenous transistors on an integrated circuit device, in accordance with any of the embodiments disclosed herein.

FIG. 8 illustrates a schematic of a cross-sectional view of an example integrated circuit device, in accordance with any of the embodiments disclosed herein.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, FinFET, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

As alluded to above, integration of different types of transistors (e.g., low voltage and high voltage, thin gate dielectric (e.g., oxide) and thick dielectric, etc.) on the same die may be difficult, especially when the different types of transistors are in the same plane and/or share the same channel material (e.g., the material of the substrate on which the transistors are built). In various embodiments, different types of transistors may be realized on the same integrated circuit device by utilizing a first channel material for a plurality of first transistors of a first type and a second channel material (e.g., a high performance (HP) thin film transistor (TFT) material) for a plurality of second transistors of a second type.

In general, a TFT is a special kind of a field-effect transistor made by depositing a thin-film of an active semiconductor material (e.g., an HP TFT material), as well as a dielectric layer and metallic contacts, over a support layer that may be a non-conducting layer. At least a portion of the active semiconductor material forms a channel of the TFT, through which charge carriers (e.g., electrons or holes) flow from a source to a drain of the transistor. This differs from conventional, non-TFT, front-end-of-line (FEOL) logic transistors where the active semiconductor channel material is typically a part of a semiconductor substrate (e.g., a crystalline substrate such as silicon).

In various embodiments, TFTs (or other transistors or circuit components comprising the HP TFT material) may be formed in the same plane as the FEOL logic transistors. In other embodiments, since an HP TFT material may be deposited at a relatively low temperature, the HP TFT material may be deposited within the thermal budgets imposed on back end fabrication to avoid damaging the front end components (e.g., logic transistors in an FEOL region) and thus the transistors or circuit components may be formed in the back-end-of-line (BEOL) region. In yet other embodiments, the transistors or circuit components comprising the HP TFT material may be formed on the back side of a wafer, opposite the front side (which may comprise the FEOL and BEOL regions).

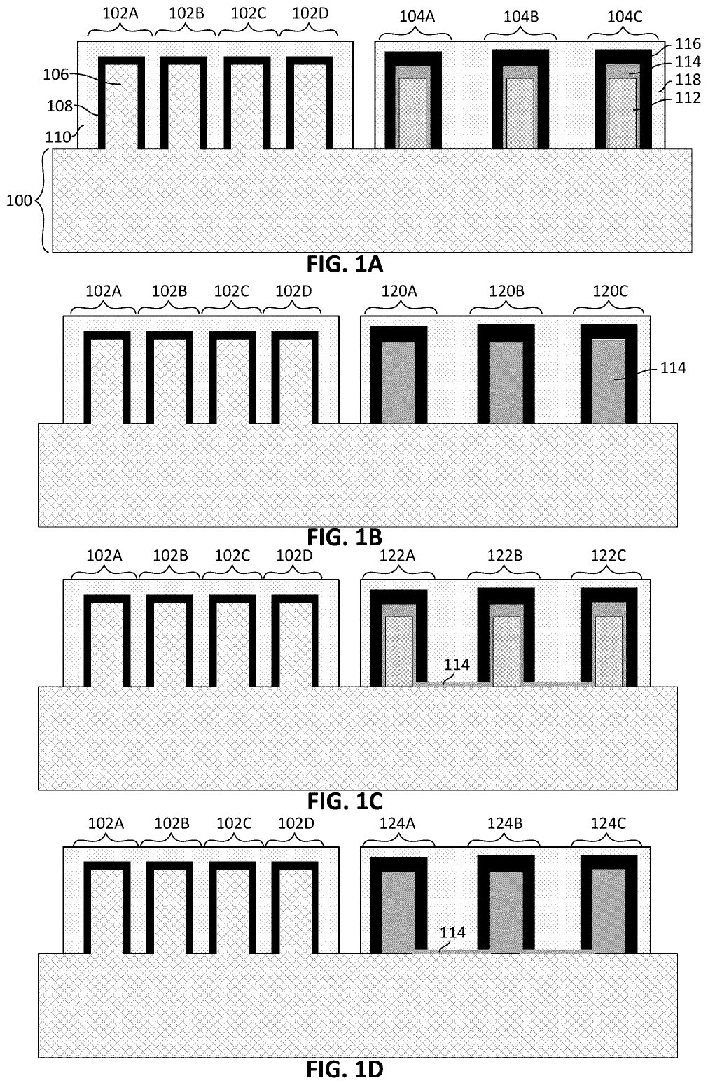

FIG. 1A illustrates a portion of an integrated circuit device comprising heterogeneous transistors. In this embodiment, the integrated circuit device comprises a plurality of first transistors 102 (e.g., 102A-D) and a plurality of second transistors 104 (e.g., 104A-D), where the first transistors and the second transistors are different types of transistors (e.g., they have different channel materials, different gate dielectric thicknesses, and/or other characteristics). The first transistors and second transistors are shown as fin field-effect transistors (FinFETs) formed on a substrate 100 (e.g., a crystalline substrate, such as silicon), but the teachings of the present disclosure may be extended to any suitable transistor topology (e.g., ribbon FETs, nanowire based transistors, nanosheet based transistors, top-gated transistors, recessed gate transistors, recessed spherical shaped gate transistors, back-gate FETs, etc.). In various embodiments, any of the transistors shown or described herein may be formed with channels comprising an HP TFT material on the same integrated circuit device with any of the transistors shown or described herein (including transistors having the same topology or different topology) with channels that do not comprise an HP TFT material (e.g., the channel material of these transistors may be the same material as the substrate upon which the transistors are formed or some other channel material).

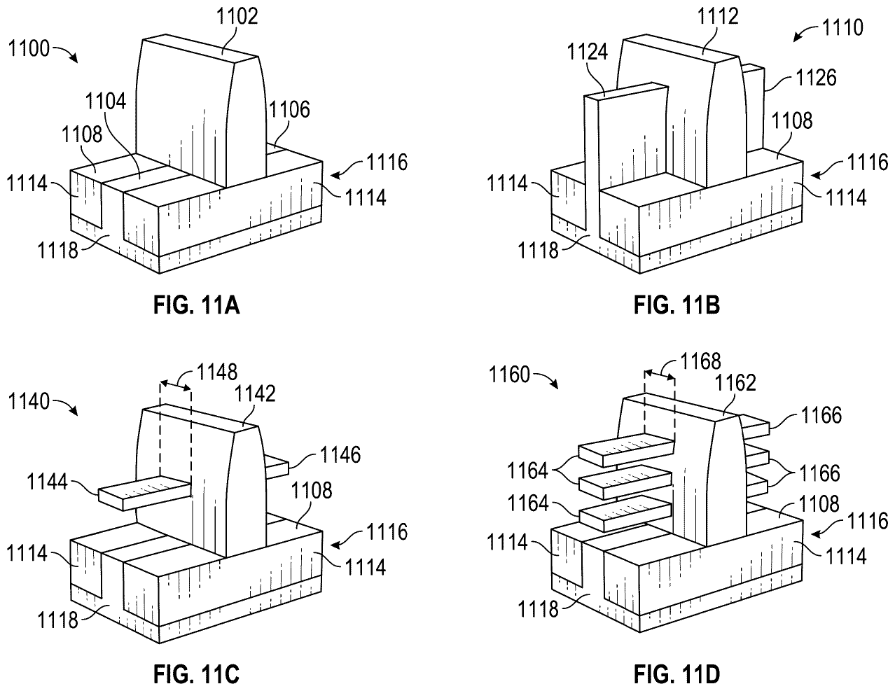

FIG. 1A (and FIGS. 1B-D) depict cross sections of various FinFETs. For example, the cross sections may be the cross section of a FinFET such as the FinFET depicted in FIG. 11B (where the cross section is taken at a point between the source and the drain). In other embodiments, the teachings of the present disclosure could be applied to the other FinFETs depicted herein (e.g., in FIGS. 11C and 11D) or other suitable FinFETs.

In various embodiments, first transistors 102 may comprise standard FinFETs in which the channel material 106 is the same material (e.g., silicon or other traditional semiconductor material) as the substrate 100. The channel material 106 is surrounded by a gate dielectric material 108 and the gate dielectric material is surrounded by a gate electrode material 110. The gate dielectric material 108 of the first transistors is relatively thin and thus the first transistors may be used in low voltage applications, but may not be suitable for high voltage applications (e.g., due to gate dielectric breakdown and/or channel breakdown).

The second transistors 104 comprise a channel material 114 that is different from the channel material 106 of the first transistors 102. In various examples, the channel material 114 is an HP TFT material (described in more detail below). In various embodiments, the channel material 114 may be deposited conformally over a structural material 112. In various embodiments, channel material 114 may be deposited using atomic layer deposition (ALD), chemical vapor deposition (CVD), or physical vapor deposition (PVD), or other suitable technique.

In the embodiment depicted in FIG. 1A, the channel material 114 is formed around a structural material 112 that is to provide structural support for the channel material 114. The structural material 112 need not (but could) be a semiconductor material. In various embodiments, the structural material 112 may be a relatively inert material, such as silicon oxide, silicon nitride, other dielectric material, a semiconductor (e.g., n-doped silicon, germanium, etc.), or other suitable material. The structural material 112 may be coated or cladded with a thin layer of the channel material 114. Channel material 114 forms the active channel for a second transistor 104.

A gate dielectric material 116 (which may or may not be the same material as the gate dielectric material 108) is formed around the channel material 114. The gate dielectric material 116 of a second transistor 104 is thicker than the gate dielectric material 108 of a first transistor 102. The second transistors 104 also include gate electrode material 118 (which may or may not be the same material as gate electrode material 110).

In addition to the gate dielectric material 116 of the second transistors 104 being thicker than the gate dielectric material 108 of the first transistors, the channel material 114 may have a wider bandgap voltage (and thus a higher breakdown voltage) than the channel material 106. This may allow the second transistors to be used in applications utilizing higher voltages as they are not as susceptible to gate dielectric and channel breakdown. For example, in various embodiments, the second transistors may be used to implement I/O circuitry.

In various embodiments, the pitch is different among the first transistors 102 and the second transistors 104. For example, the pitch between adjacent first transistors may be smaller than the pitch between adjacent second transistors. This may lead to manufacturing difficulties if the first transistors and the second transistors were to be manufactured with the same channel material (e.g., the substrate material) that are alleviated by using a separate channel material in the second transistors.

When the second transistors are cointegrated in the same plane as the first transistors (e.g., as depicted in FIG. 1A), etching to form the structures of the channel material 106 and the structures of the structural material 112 may be performed in the same process step (at least in some embodiments). The channel material 106 of the eventual first transistors 102 may then be masked while the channel material 114 of the eventual second transistors 104 is deposited on the structural material 112 (and on the substrate 100 at the base of the structural material 112). Accordingly, two different types of semiconductors may be formed on the same wafer with only a minor processing change.

In other embodiments, the second transistors 104 built using the channel material 114 may alternatively (or additional second transistors 104 may) be manufactured in a different plane (e.g., integrated in the backend or on the backside of the wafer) from the first transistors 102.

FIG. 1B illustrates a portion of an integrated circuit device comprising heterogeneous transistors. This embodiment includes first transistors 102 and second transistors 120 (e.g., 120A-C). The second transistors 120 may have any suitable characteristics of the second transistors 104. However, in this embodiment, the second transistors 120 omit the structural material 112. Rather, the channel material 114 occupies the area that was occupied by structural material 112 in FIG. 1A. In this embodiment, the channel material 114 is deposited over (e.g., directly on) the substrate 100 and the channel material 114 forms the fins of the FinFETs.

FIG. 1C illustrates a portion of an integrated circuit device comprising heterogeneous transistors. This embodiment includes first transistors 102 and second transistors 122 (e.g., 122A-C). The second transistors 122 may have any suitable characteristics of the second transistors 104. In this embodiment, the channel material 114 is continuous between adjacent second transistors 122 (whereas in the embodiments shown in FIGS. 1A and 1B the channel material 114 of a second transistor 104 or 120 is separated from the channel material 114 of its adjacent second transistors 104 or 120, e.g., by gate dielectric material 116 and gate electrode material 118). In the embodiment depicted, this continuity is provided by a thin layer of channel material 114 running from the bottom of the structural material of a second transistor 122 underneath the gate dielectric material 116 and gate electrode material 118 to the bottom of the structural material of an adjacent second transistor 122.

FIG. 1D illustrates a portion of an integrated circuit device comprising heterogeneous transistors. This embodiment combines characteristics of the second transistors 120 and 122 of FIGS. 1B and 1C in that a structural material (e.g., 112) is not used and the channel material 114 is continuous between adjacent second transistors 124. Second transistors 124 may have any suitable characteristics of second transistors 104, 120, or 122.

Although the transistors 104, 120, 122, and 124 are shown as being formed on substrate 100, in other embodiments, the transistors may be formed on a dielectric material (e.g., a non-crystalline substrate comprising, e.g., silicon oxide, silicon nitride, a metal oxide, a silicon oxynitride). In some embodiments, a non-crystalline substrate may refer to a wafer or thin templating layer that is amorphous, polycrystalline, or nanocrystalline (e.g., each nanocrystallite grain not exceeding 1 nanometer), e.g., it has a short range order. The non-crystalline substrate may be a layer or a bulk substrate.

As described above, in some embodiments, the channel material 114 comprises a high performance (HP) thin film transistor (TFT) material. An HP TFT material may comprise a semiconductor material exhibiting a high mobility and a wide bandgap voltage. In various embodiments, the HP TFT material is not a single crystalline material (e.g., silicon), but is amorphous, polycrystalline, or nanocrystalline.

In various embodiments, the charge carrier mobility of the HP TFT material is higher than 5 cm cm²/(V·s), higher than 20 cm²/(V·s), higher than 50 cm²/(V·s), or higher than 100 cm²/(V·s). In various embodiments, the mobility of the HP TFT material is between 5 cm²/(V·s) and 700 cm²/(V·s), including all values and ranges therein (including the range from 50 cm²/(V·s) to 700 cm²/(V·s) and the range from 100 cm²/(V·s) to 700 cm²/(V·s)). At least in some embodiments, these ranges may be critical as they represent a range for mobility that is high enough to function as an HP TFT channel material, which is generally difficult to achieve with an amorphous, nanocrystalline, or polycrystalline material. In various embodiments, the bandgap voltage of the HP TFT material is higher than the bandgap voltage of silicon (e.g., 1.14 eV @ 300K). In some examples, the bandgap voltage of the HP TFT material is materially higher than the bandgap voltage of silicon (e.g., higher than 1.2 eV @ 300K). In particular embodiments, the bandgap voltage of the HP TFT material is higher than the bandgap voltage of silicon but lower than 6.5 eV @ 300K, including all values and ranges therein. In various embodiments, the bandgap voltage of the HP TFT material is higher than the bandgap voltage of a substrate upon which a transistor comprising the HP TFT material is formed. These ranges may be critical as they represent a range for a bandgap voltage that may protect against channel breakdown.

In various embodiments, the HP TFT material comprises an oxide (e.g., a metal oxide), such as indium gallium zinc oxide (IGZO), indium tin oxide (ITO), indium zinc oxide (IZO), zinc oxide, indium oxide, gallium oxide, copper oxide, tin oxide, or other suitable oxide. In some oxides, a material with insulating properties may be introduced into the oxide to increase the bandgap voltage. For example, doping indium oxide with hafnium oxide (which exhibits insulating properties) will result in a composite HP TFT material with a wider bandgap than the indium oxide. Similarly, indium oxide or zinc oxide may be doped with gallium oxide (which exhibits insulating properties) to produce a composite HP TFT material with a wider bandgap voltage.

In some embodiments, the HP TFT material comprises a nitride (e.g., a metal nitride), such as zinc nitride, indium nitride, gallium nitride, copper nitride, aluminum nitride, or other suitable nitride. In some nitrides, a material with insulating properties may be introduced into the nitride to increase the bandgap voltage. For example, aluminum nitride (which exhibits insulating properties) may be added to indium nitride, zinc nitride, or gallium nitride to produce a composite HP TFT material with an increased bandgap voltage.

In some embodiments, the HP TFT material comprises a chalcogenide, such as a selenide or sulfide of molybdenum, tungsten, indium, gallium, zinc, copper, hafnium, aluminum, or germanium.

In some embodiments, the HP TFT material comprises any other suitable material, such as black phosphorous, graphene, carbon nanotubes, polysilicon, poly germanium, poly (3,5) (gallium arsenide, etc.). While some of these materials have a narrower bandgap voltage than silicon in certain compositions, the concentration of certain elements (e.g., gallium) may be increased to improve the bandgap voltage of the resulting HP TFT material.

In one example, a transistor may comprise an HP TFT material comprising a nitride (e.g., InN, InZnN, GaN, InGaN with oxygen, sulphur and/or phosphorus additions). In another example, the transistor may comprise an HP TFT material comprising a ZnN film with a bandgap voltage ranging from 1.3 to 3 eV (depending on the N content) with a mobility exceeding 100 cm²/Vs. The transistor may also comprise a gate dielectric comprising HfZrOx and/or a gate electrode material comprising Ta, Ti, TiN or W.

Substrate 100 and channel material 106 (or substrates or channel materials of any other standard transistors that may be integrated with transistors with channels formed of HP TFT material having various topologies described herein) may comprise, for example, a bulk substrate including group IV semiconductor material (such as silicon, germanium, or silicon germanium), group III-V semiconductor material (such as gallium arsenide, indium gallium arsenide, or indium phosphide), and/or any other suitable material from and/or upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers of indium gallium arsenide and indium phosphide).

Although the source and drain (S/D) electrodes (also referred to as terminals) of transistors 102 and 104 aren't shown in FIG. 1A because a cross section is depicted at the channels, the S/D electrodes may be coupled to the respective channel material 106 or channel material 114 (e.g., at locations into the page and out of the page). As is commonly known, source and drain terminals are interchangeable in transistors (hence, the notation “S/D” terminals is sometimes used, indicating the interchangeability of the source and drain terminals). Therefore, while some examples and illustrations may be presented here with reference to source and drain electrodes, in other embodiments, any of source or drain terminals may be reversed.

S/D electrodes may include any suitable electrically conductive material, alloy, or a stack of multiple electrically conductive materials. In some embodiments, the S/D electrodes may include one or more metals or metal alloys, comprising one or metals, e.g., copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the S/D electrodes may include one or more electrically conductive alloys, oxides, or carbides of one or more metals. In some embodiments, the S/D electrodes may include a doped semiconductor, such as silicon or another semiconductor doped with an N-type dopant or a P-type dopant. Metals may provide higher conductivity, while doped semiconductors may be easier to pattern during fabrication.

A gate dielectric material (e.g., 108 or 116) may be provided to separate (e.g., to be between) the channel materials (e.g., 106 or 114) and the respective gate electrode material (e.g., 110 or 118). In various embodiments, a gate dielectric may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric to improve its quality when a high-k material is used.

In some cases, a gate dielectric may include multiple layers, such as a first layer of high-k material (e.g., hafnium oxide) in contact with a gate electrode and a second layer of lower-k oxide between the first layer and the channel material. The lower-k oxide may be, for instance, silicon oxide or an oxide of the channel layer material. In various embodiments, the one or more layers of a gate dielectric may include e.g., silicon oxide, silicon dioxide, silicon carbide, and/or other suitable dielectric material.

A gate electrode material (e.g., 110 or 118) of a transistor (e.g., 102 or 104) may include any suitable conductive material such as polysilicon, a metal, or a metal alloy. Example suitable metals or metal alloys include aluminum, tungsten, cobalt, molybdenum, ruthenium, titanium, tantalum, copper, and carbides and nitrides thereof. In various embodiments, a gate electrode may include at least one P-type work function metal or N-type work function metal, depending on whether the respective transistor is a P-type transistor or an N-type transistor. For a P type transistor, metals that may be used for the gate electrode may include, but are not limited to, ruthenium, gold, palladium, platinum, cobalt, nickel, and conductive metal oxides (e.g., ruthenium oxide). For an N type transistor, metals that may be used for the gate electrode include, but are not limited to, hafnium, zirconium, titanium, tantalum, aluminum, alloys of these metals, and carbides and nitrides of these metals (e.g., hafnium carbide, zirconium carbide, titanium carbide, tantalum carbide, aluminum carbide, titanium nitride, and tantalum nitride).

In some embodiments, a gate electrode may include a stack of two or more metal layers, where one or more metal layers are work function metal layers and at least one metal layer is a fill metal layer or inner plug layer. Further metal layers may be included for other purposes, such as to act as a diffusion barrier layer.

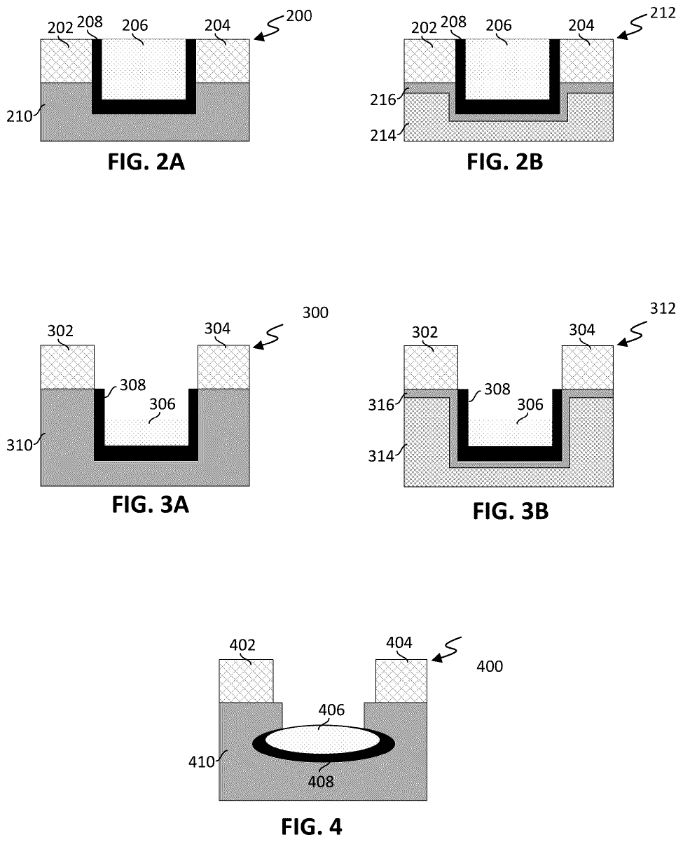

As alluded to above, in various embodiments, the HP TFT material may be used to form transistors of various topologies. Various elements of these transistors (e.g., gate electrodes, D/S electrodes, channel materials, gate dielectric materials, structural materials, substrates, etc.) may have any suitable characteristics of corresponding elements described above or elsewhere herein. As examples of various topologies that may include a channel formed by an HP TFT material, FIGS. 2A and 2B illustrate top-gated transistors, FIGS. 2C and 2D illustrate recessed gate transistors, and FIG. 2E illustrates a recessed spherical shaped gate transistor. Each of these transistors comprise an HP TFT material forming a channel between a source and a drain of the respective transistor. In various embodiments, any of these transistors may be formed on a substrate of the same integrated circuit device with transistors having similar topologies, but in which the channel material does not include an HP TFT material (e.g., channel material that is the same material as the substrate upon which the transistors are formed).

FIG. 2A depicts a top-gated transistor 200. The transistor 200 comprises a source electrode 202, a drain electrode 204, a gate electrode 206, a gate dielectric 208, and channel material 210 comprising an HP TFT material. The source electrode 202, drain electrode 204, and channel material 210 are each separated from the gate electrode 206 by the gate dielectric 208. In various embodiments, the channel material 210 may be formed over a substrate (e.g., similar to substrate 100) or elsewhere over a dielectric material (e.g., a non-crystalline substrate, comprising, e.g., silicon oxide, silicon nitride, a metal oxide, a silicon oxynitride). In the top-gated transistor 200 depicted, the top of the gate electrode 206 is at the same height as the source electrode 202 and drain electrode 204.

FIG. 2B depicts a top-gated transistor 212 that is similar to the transistor 200, with the exception that the transistor 212 comprises a structural material 214 formed underneath the source electrode 202, drain electrode 204, and gate dielectric 208. A channel material 216 comprising a thin layer of HP TFT material is formed on top of the structural material 214.

FIG. 3A depicts a recessed gate transistor 300. The transistor 300 comprises a source electrode 302 and a drain electrode 304, a recessed gate electrode 306, a gate dielectric 308, and a channel material 310 comprising an HP TFT material. In this embodiment, the gate electrode 306 is offset (e.g., lower) from the source electrode 302 and drain electrode 304. The source electrode 302, drain electrode 304, and channel material 310 are each separated from the gate electrode 306 by the gate dielectric 308. In various embodiments, the channel material 310 may be formed over a substrate (e.g., similar to substrate 100) or elsewhere over a dielectric material.

FIG. 3B depicts a recessed gate transistor 312 that is similar to the transistor 300, with the exception that the transistor 312 comprises a structural material 314 formed below the source electrode 302, drain electrode 304, and gate dielectric 308. A channel material 316 comprising a thin layer of HP TFT material is formed on top of the structural material 314 and underneath source electrode 302, drain electrode 304, and gate dielectric 308. In various embodiments, the structural material 314 may be an insulating material.

FIG. 4 illustrates a recessed spherical shaped gate transistor 400. The transistor 400 comprises a source electrode 402 and a drain electrode 404, a gate electrode 406, a gate dielectric 408, and a channel material 410 comprising an HP TFT material. The gate electrode 406 and the gate dielectric 408 each have a generally spherical shape (in various embodiments this shape profile may be achieved using a wet etch). The gate dielectric 408 separates the gate electrode 406 from the channel material 410. In various embodiments, the channel material 410 may be formed over a substrate (e.g., similar to substrate 100) or elsewhere over a dielectric material.

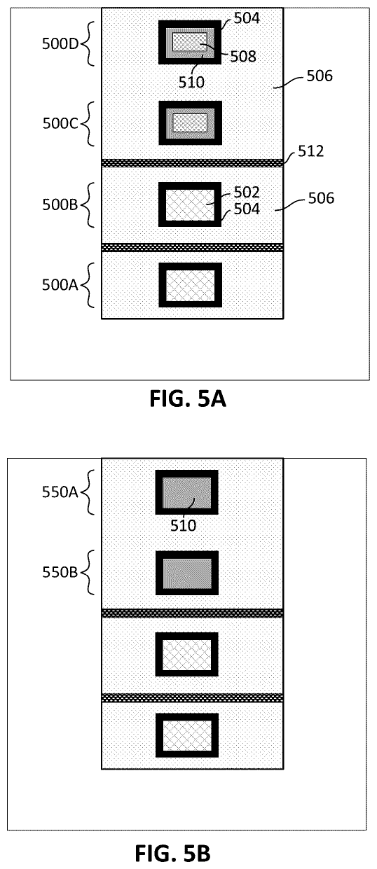

FIG. 5A illustrates a cross section of a nanowire based transistor architecture utilizing an HP TFT material as a channel. In this illustration, the nanowires extend orthogonal to the plane depicted (e.g., into and out of the page). The architecture includes transistors 500 (e.g., 500A-D). Transistors 500A and 500B depict standard nanowire based transistors, in which a transistor is formed by a nanowire 502 comprising a semiconductor material surrounded by a gate dielectric 504 and gate electrode material 506. The nanowire 502 may form a channel between a source electrode and a drain electrode (not shown).

The architecture may also include nanowire based transistors comprising nanowires with a structural material 508 coated around the outer edge with an channel material material 510 comprising an HP TFT material. The structural material 508 may be any suitable material, such as, e.g., any of the materials described above with respect to structural material 112. The channel material 510 is surrounded by gate dielectric 504 (in other embodiments, the channel material 510 could be surrounded by a gate dielectric that is different from the gate dielectric surrounding the nanowires of the standard transistors (e.g. 500A, 500B)). The gate dielectric 504 is itself surrounded by gate electrode material 506 (in other embodiments, the composition of the gate electrode material may be different from the composition of the gate electrode material of the standard transistors).

In some embodiments, the gate electrode material 506 surrounding one or more nanowires may be separated from gate electrode material 506 surrounding one or more other nanowires by a dielectric layer 512. In various embodiments, any number of nanowires may be stacked over each other in this manner.

Although these embodiments depict nanowires, the teachings herein may be expanded to other similar architectures. For example, transistors based on nanosheets or nanoribbons may also utilize the HP TFT material as a channel material in a similar fashion.

FIG. 5B illustrates a cross section of a nanowire based transistor architecture that is similar to the architecture of FIG. 5A, with the exception that the nanowires of transistors 550A and 550B do not include the structural material 508, but rather the entire volume inside of the gate dielectric 504 comprises the channel material 510 comprising the HP TFT material.

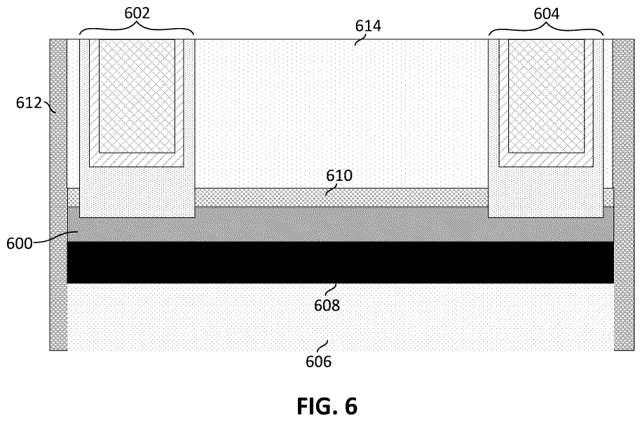

As described above, transistors with channel material comprising HP TFT material may be included on the front side (e.g., FEOL, BEOL) or the backside of a wafer. FIG. 6 illustrates a backgate FET that may include a channel material 600 comprising an HP TFT material. In various embodiments, the backgate FET may be included within the BEOL.

According to some embodiments, the backgate FET is a TFT structure that includes a gate electrode 606, a gate dielectric 608 over the gate electrode, a channel material 600 over the gate dielectric 608, and a source electrode 602 and drain electrode 604 coupled to the channel material 600.

The channel material 600 connects the source electrode 602 of the backgate FET to the drain electrode 604. In the embodiment depicted, the backgate FET also includes a layer of aluminum oxide 610 above the channel material 600 and is bounded on the sides by hafnium oxide 612. Finally, a hard mask material 614 (e.g., silicon nitride) may be formed between and the source electrode 602 and drain electrode 604.

In various embodiments, the entire portion shown as channel material 600 may be formed with the HP TFT. In other embodiments, only a thin layer of this area may comprise the HP TFT material and the remainder of this area may comprise a structural material.

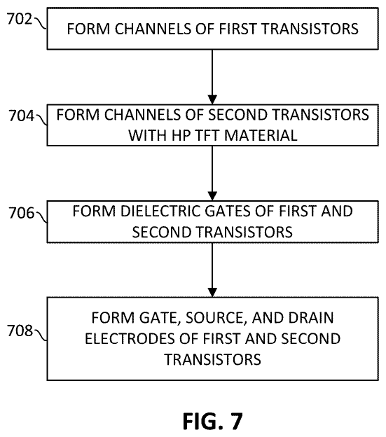

FIG. 7 illustrates a method for forming heterogenous transistors on an integrated circuit device, in accordance with any of the embodiments disclosed herein. At 702 channels of first transistors are formed. These channels may be formed in any suitable manner. For example, in some embodiments these channels may be formed from a substrate material (e.g., via etching or other suitable process). At 704 channels of second transistors are formed with an HP TFT material. These channels may be formed in any suitable manner. For example, in some embodiments these channels may be formed by depositing the HP TFT material (e.g., on a crystalline or non-crystalline substrate and/or on a structural material) and then removing (e.g., through etching or other suitable process) unwanted portions of the HP TFT material. At 706, dielectric gates of first and second transistors are formed. At 708, gate source, and drain electrodes of the first and second transistors are formed. The operations and suboperations of FIG. 7 may be performed in any suitable order.

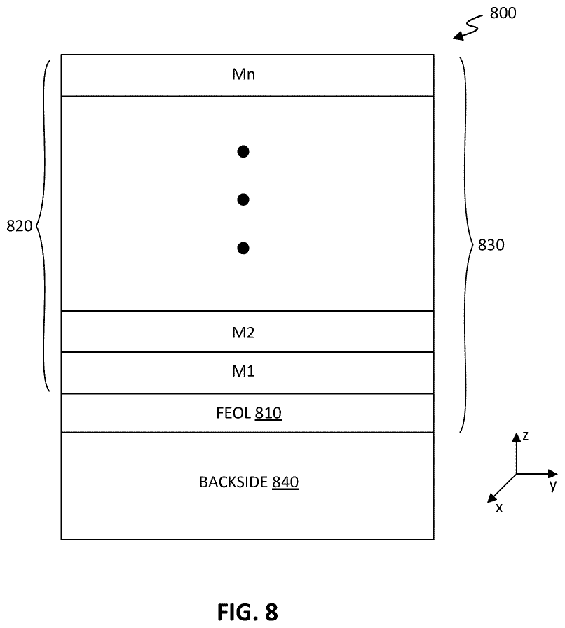

FIG. 8 provides a schematic illustration of a cross-sectional view of an example integrated circuit device (e.g., a chip) 800, according to some embodiments of the present disclosure. The IC device 800 may include any one or more of the transistors topologies shown herein (or other transistor topologies) including standard transistors and transistors with channel material comprising an HP TFT material.

As shown in FIG. 8, the IC device 800 may include a front side 830 comprising an FEOL 810 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 810 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within the BEOL 820.

The front side 830 of the IC device 800 also includes a BEOL 820 including various metal interconnect layers (e.g., metal 1 through metal n, where n is any suitable integer). Various metal layers of the BEOL 820 may be used to interconnect the various inputs and outputs of the FEOL 810.

Generally speaking, each of the metal layers of the BEOL 820, e.g., each of the layers M1-Mn shown in FIG. 8, may include a via portion and a trench/interconnect portion. Typically, the trench portion of a metal layer is above the via portion, but, in other embodiments, a trench portion may be provided below a via portion of any given metal layer of the BEOL 820. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 820, e.g., layers M1-Mn shown in FIG. 8, may include certain patterns of conductive metals, e.g., copper (Cu) or aluminum (Al), or metal alloys, or more generally, patterns of an electrically conductive material, formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 800 may also include a backside 840. For example, the backside 840 may formed on the opposite side of a wafer from the front side 830. In various embodiments, the backside 840 may include any suitable elements to assist operation of the IC device 800. For example, the backside 840 may include various metal layers to deliver power to logic of the FEOL 810. In some embodiments, transistors or other circuit elements including HP TFT material may be formed on the backside 840 of the IC device 800.

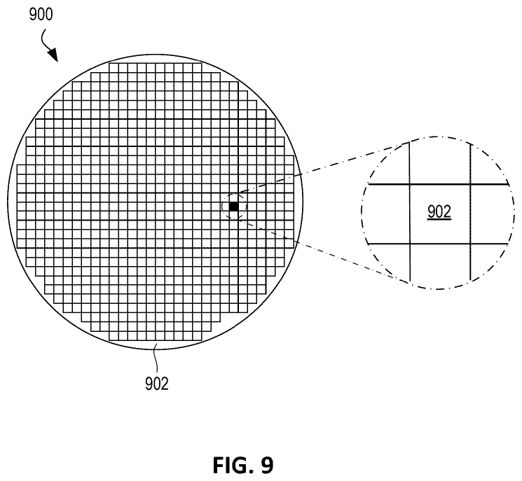

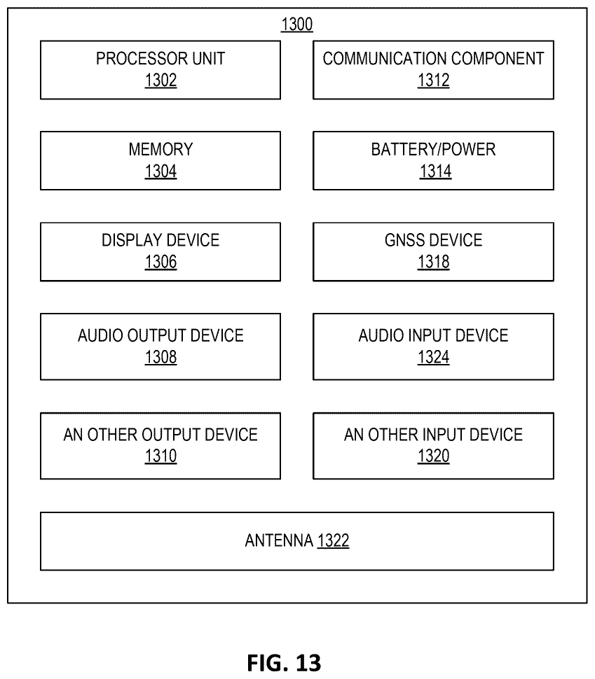

FIG. 9 is a top view of a wafer 900 and dies 902 wherein individual dies may include heterogeneous transistors as described herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1140 of FIG. 11, discussed below and/or heterogeneous transistors as described herein), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, OTP RAM, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array.

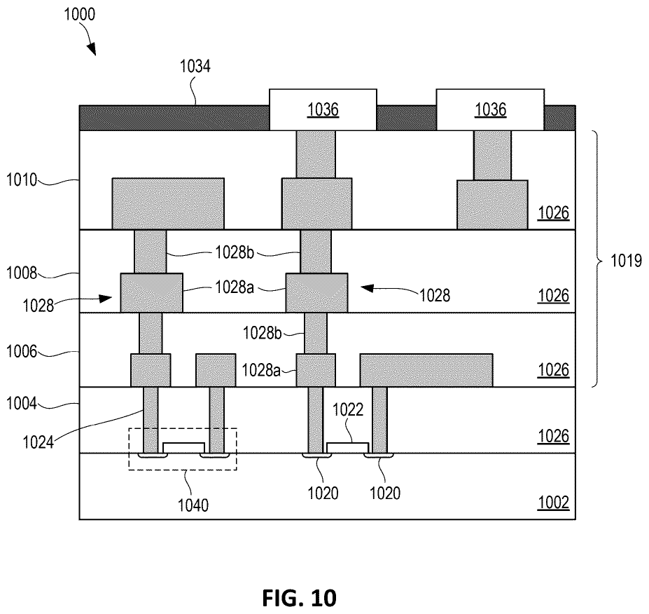

FIG. 10 is a cross-sectional side view of an integrated circuit device 1000 that may include heterogeneous transistors as described herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. Examples and characteristics of gate dielectrics and gate electrodes have been described above.

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020. Further examples of materials that may be used to form the S/D regions are provided above.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (e.g., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the integrated circuit device (e.g., die) 1000, and the metallization stack 1019 can be used to route I/O signals from the conductive contacts 1036 to transistors 1040 and any other components integrated into the integrated circuit device (e.g., die) 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

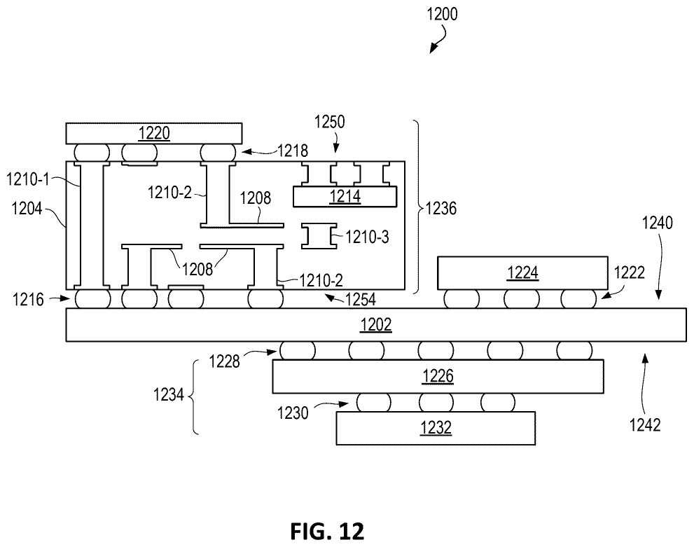

FIG. 12 is a cross-sectional side view of an integrated circuit device assembly 1200. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10, etc.) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include heterogeneous transistors as disclosed herein. For example, any suitable ones of the components of the electrical device 1300 may include one or more of the integrated circuit device assemblies 1200, integrated circuit components 1220, integrated circuit devices 1100, or integrated circuit dies 902 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include another output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first gate and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

The following are examples of subject matter described herein:

Example 1 includes an integrated circuit device comprising a plurality of first field effect transistors (FETs) formed on a substrate, wherein a first FET comprises a first channel material comprising a portion of the substrate; and a plurality of second FETs formed on the substrate, wherein a second FET comprises a second channel material that is different from the first channel material, wherein the second channel material comprises a thin film transistor (TFT) channel material.

Example 2 includes the subject matter of Example 1, and wherein the TFT channel material has a charge carrier mobility within a range of 50 cm²/(V·s) to 700 cm²/(V·s) and a bandgap voltage within a range of 1.15 eV to 6.5 eV at 300 degrees Kelvin.

Example 3 includes the subject matter of any of Examples 1 and 2, and wherein first FETs are separated by a first average pitch and second FETs are separated by a second average pitch that is greater than the first average pitch.

Example 4 includes the subject matter of any of Examples 1-3, and wherein the second FETs comprise gate dielectrics that are thicker than gate dielectrics of the first FETs and wherein the second FETs are adapted to operate at a higher voltage than the first FETs.

Example 5 includes the subject matter of any of Examples 1-4, and wherein the plurality of first FETs and the plurality of second FETs are FinFETs.

Example 6 includes the subject matter of any of Examples 1-5, and wherein the plurality of first FETs and the plurality of second FETs are top-gated transistors, recessed gate transistors, or recessed spherical shaped gate transistors.

Example 7 includes the subject matter of any of Examples 1-6, and further including a structural material on the substrate, wherein the channel material of the second FET coats a portion of the structural material that is not in contact with the substrate.

Example 8 includes the subject matter of any of Examples 1-7, and wherein the second channel material forms a coating around at least a portion of a structural material.

Example 9 includes the subject matter of any of Examples 1-8, and wherein the structural material comprises silicon oxide or silicon nitride.

Example 10 includes an integrated circuit device comprising a plurality of first field effect transistors (FETs), wherein a first field effect transistor comprises a first channel material; and a plurality of second FETs, wherein a second FET comprises a second channel material that is different from the first channel material, wherein the second channel material comprises a thin film transistor (TFT) channel material having a charge carrier mobility within a range of 50 cm²/(V·s) to 700 cm²/(V·s) and a bandgap voltage within a range of 1.15 eV to 6.5 eV at 300 degrees Kelvin.

Example 11 includes the subject matter of Example 10, and wherein the first FETs are formed on a substrate and the first channel material comprises a portion of the substrate.

Example 12 includes the subject matter of any of Examples 10 and 11, and wherein first FETs are separated by a first average pitch and second FETs are separated by a second average pitch that is greater than the first average pitch.

Example 13 includes the subject matter of any of Examples 10-12, and wherein the second FETs comprise gate dielectrics that are thicker than gate dielectrics of the first FETs and wherein the second FETs are adapted to operate at a higher voltage than the first FETs.

Example 14 includes the subject matter of any of Examples 10-13, and wherein the second FETs are FinFETs.

Example 15 includes the subject matter of any of Examples 10-14, and wherein the second FETs comprise nanowires or nanosheets comprising the second channel material.

Example 16 includes the subject matter of any of Examples 10-15, and wherein the second FETs comprise backgate FETs.

Example 17 includes the subject matter of any of Examples 10-16, and wherein the second FETs comprise top-gated transistors, recessed gate transistors, or recessed spherical shaped gate transistors.

Example 18 includes the subject matter of any of Examples 10-17, and wherein the second channel material forms a coating around at least a portion of a structural material.

Example 19 includes the subject matter of any of Examples 10-18, and wherein the structural material comprises silicon oxide or silicon nitride.

Example 20 includes the subject matter of any of Examples 10-19, and wherein the first channel material comprises a portion of a silicon substrate.

Example 21 includes the subject matter of any of Examples 10-20, wherein the first FETs are on a front side of the integrated circuit device and the second FETs are on a back side of the integrated circuit device.

Example 22 includes a method comprising forming a plurality of first field effect transistors (FETs) with channels having a first channel material; and forming a plurality of second FETs with channels having a second channel material that is different from the first channel material, wherein the second channel material comprises a thin film transistor (TFT) channel material having a charge carrier mobility within a range of 50 cm²/(V·s) to 700 cm²/(V·s) and a bandgap voltage within a range of 1.15 eV to 6.5 eV at 300 degrees Kelvin.

Example 23 includes the subject matter of Example 22, and wherein the first channel material is a substrate, wherein forming the plurality of second FETs comprises depositing the second channel material on the substrate.

Example 24 includes the subject matter of any of Examples 22 and 23, and wherein forming the plurality of second FETs comprises depositing a structural material on a substrate and depositing the second channel material on the structural material.

Example 25 includes the subject matter of any of Examples 22-24, and wherein the first channel material is a crystalline substrate, wherein forming the plurality of second FETs comprises depositing the second channel material on a non-crystalline substrate.

Example 26 includes the subject matter of any of Examples 22-25, and wherein first FETs are separated by a first average pitch and second FETs are separated by a second average pitch that is greater than the first average pitch.

Example 27 includes the subject matter of any of Examples 22-26, and wherein the second FETs comprise gate dielectrics that are thicker than gate dielectrics of the first FETs and wherein the second FETs are adapted to operate at a higher voltage than the first FETs.

Example 28 includes the subject matter of any of Examples 22-27, and wherein the second FETs are FinFETs.

Example 29 includes the subject matter of any of Examples 22-28, and wherein the second FETs comprise nanowires or nanosheets comprising the second channel material.

Example 30 includes the subject matter of any of Examples 22-29, and wherein the second FETs comprise backgate FETs.

Example 31 includes the subject matter of any of Examples 22-30, and wherein the second FETs comprise top-gated transistors, recessed gate transistors, or recessed spherical shaped gate transistors.

Example 32 includes the subject matter of any of Examples 22-31, and wherein the second channel material forms a coating around at least a portion of a structural material.

Example 33 includes the subject matter of any of Examples 22-32, and wherein the structural material comprises silicon oxide or silicon nitride.

Example 34 includes the subject matter of any of Examples 22-33, and wherein the first FETs are on a front side of the integrated circuit device and the second FETs are on a back side of the integrated circuit device.

Example 35 includes the subject matter of any of Examples 22-34, and wherein the TFT channel material comprises a zinc nitride film.

Example 36 includes the subject matter of any of Examples 1-21, and further comprising an integrated circuit die comprising the plurality of first FETs and the plurality of second FETs.

Example 37 includes the subject matter of any of Examples 1-21 and 36, and further comprising a circuit board coupled to the integrated circuit die.

Example 38 includes the subject matter of any of Examples 1-21 or 36-37, and further comprising at least one of a network interface, battery, or memory coupled to the integrated circuit die.

1. An integrated circuit device comprising:
a plurality of first field effect transistors (FETs) formed on a substrate, wherein a first FET of the plurality of first FETs comprises a first channel material comprising a portion of the substrate; and
a plurality of second FETs formed on the substrate, wherein a second FET of the plurality of second FETs comprises a second channel material that is different from the first channel material, wherein the second channel material comprises a thin film transistor (TFT) channel material.

2. The integrated circuit device of claim 1, wherein the TFT channel material has a charge carrier mobility within a range of 50 cm²/(V·s) to 700 cm²/(V·s) and a bandgap voltage within a range of 1.15 eV to 6.5 eV at 300 degrees Kelvin.

3. The integrated circuit device of claim 1, wherein the plurality of first FETs are separated by a first average pitch and the plurality of second FETs are separated by a second average pitch that is greater than the first average pitch.

4. The integrated circuit device of claim 1, wherein the plurality of second FETs comprise gate dielectrics that are thicker than gate dielectrics of the plurality of first FETs and wherein the plurality of second FETs are adapted to operate at a higher voltage than the plurality of first FETs.

5. The integrated circuit device of claim 1, wherein the plurality of first FETs and the plurality of second FETs are FinFETs.

6. The integrated circuit device of claim 1, wherein the plurality of first FETs and the plurality of second FETs are top-gated transistors, recessed gate transistors, or recessed spherical shaped gate transistors.

7. The integrated circuit device of claim 1, further comprising a structural material on the substrate, wherein the second channel material of the second FET coats a portion of the structural material that is not in contact with the substrate.

8. The integrated circuit device of claim 1, further comprising an integrated circuit die comprising the plurality of first FETs and the plurality of second FETs.

9. The integrated circuit device of claim 1, further comprising a circuit board coupled to the integrated circuit die.

10. The integrated circuit device of claim 9, further comprising at least one of a network interface, battery, or memory coupled to the integrated circuit die.

11. An integrated circuit device comprising:
a plurality of first field effect transistors (FETs), wherein a first FET comprises a first channel material; and
a plurality of second FETs, wherein a second FET comprises a second channel material that is different from the first channel material, wherein the second channel material comprises a thin film transistor (TFT) channel material having a charge carrier mobility within a range of 50 cm²/(V·s) to 700 cm²/(V·s) and a bandgap voltage within a range of 1.15 eV to 6.5 eV at 300 degrees Kelvin.

12. The integrated circuit device of claim 11, wherein the second FETs are FinFETs.

13. The integrated circuit device of claim 11, wherein the second FETs comprise nanowires or nanosheets comprising the second channel material.

14. The integrated circuit device of claim 11, wherein the second FETs comprise backgate FETs.

15. The integrated circuit device of claim 11, wherein the second channel material forms a coating around at least a portion of a structural material.

16. The integrated circuit device of claim 11, wherein the first channel material comprises a portion of a silicon substrate.

17. The integrated circuit device of claim 11, wherein the first FETs are on a front side of the integrated circuit device and the second FETs are on a back side of the integrated circuit device.

18. A method comprising:
forming a plurality of first field effect transistors (FETs) with channels having a first channel material; and
forming a plurality of second FETs with channels having a second channel material that is different from the first channel material, wherein the second channel material comprises a thin film transistor (TFT) channel material having a charge carrier mobility within a range of 50 cm²/(V·s) to 700 cm²/(V·s) and a bandgap voltage within a range of 1.15 eV to 6.5 eV at 300 degrees Kelvin.

19. The method of claim 18, wherein the first channel material is a substrate, wherein forming the plurality of second FETs comprises depositing the second channel material on the substrate.

20. The method of claim 18, wherein the TFT channel material comprises a zinc nitride film.
